(19) United States
(12) Patent Application Publication
(10) Pub. No.: US 2010/0087069 A1
(43) Pub. Date: Apr. 8, 2010

(54) METHOD OF MANUFACTURING SEMICONDUCTOR DEVICE AND SUBSTRATE PROCESSING APPARATUS

(75) Inventors: Hironobu MIYA, Toyama-shi (JP); Kazuyuki Toyoda, Toyama-shi (JP); Masanori Sakai, Takaoka-shi (JP); Norikazu Mizuno, Toyama-shi (JP); Tsutomu Kato, Takaoka-shi (JP); Yuji Takebayashi, Toyama-shi (JP); Kenji Ono, Toyama-shi (JP); Atsushi Morikawa, Toyama-shi (JP); Satoshi Okada, Toyama-shi (JP)

Correspondence Address: BRUNDIDGE & STANGER, P.C., 1700 DIAGONAL ROAD, SUITE 330, ALEXANDRIA, VA, 22314, US

(73) Assignee: Hitachi-Kokusai Electric Inc.

(21) Appl. No.: 12/571,688

(22) Filed: Oct. 1, 2009

(30) Foreign Application Priority Data
Oct. 7, 2008 (JP) 2008-260665
Jul. 31, 2009 (JP) 2009-179630

(51) Int. Cl. H01L 21/316; C23C 16/46; C23C 16/513

(52) U.S. Cl. 438/778; 118/725; 118/723 E; 257/E21.274

(57) ABSTRACT

The coverage characteristics or loading effect of an oxide film can be improved without having to increase the supply amount or time of an oxidant. There is provided method of manufacturing a semiconductor device. The method comprises loading at least one substrate to a processing chamber; forming an oxide film on the substrate by alternately supplying a first reaction material and a second reaction material containing oxygen atoms to the processing chamber while heating the substrate; and unloading the substrate from the processing chamber, wherein the forming of the oxide film is performed by keeping the substrate at a temperature equal to or lower than a self-decomposition temperature of the first reaction material and irradiating ultraviolet light to the second reaction material.

### CROSS-REFERENCE TO RELATED PATENT APPLICATION

This U.S. non-provisional patent application claims priority under 35 U.S.C. §119 of Japanese Patent Application Nos. 2008-260665, filed on Oct. 7, 2008, and 2009-179630, filed on Jul. 31, 2009, in the Japanese Patent Office, the entire contents of which are hereby incorporated by reference.

### BACKGROUND OF THE INVENTION

1. Field of the Invention

The present invention relates to a method of manufacturing a semiconductor device and a substrate processing apparatus, more particularly, to an effective technique for forming a metal oxide film on a process-target substrate.

2. Description of the Prior Art

Recently, as the integration level of semiconductor devices is highly increased, it is necessary to form a much thinner insulating film during a device forming process. However, since a tunnel current flows if the thickness of the insulating film is small, it is desired that the thickness of the insulating film is effectively reduced while maintaining the thickness of the insulating film at a level where the tunnel effect does not occur, and high dielectric constant (high-k) metal oxides such as HfO₂ and ZrO₂ are drawing attraction as capacitor materials. For example, it is difficult to impose electrical restrictions when a film is formed to a thickness of 1.6 nm by using SiO₂; however, an equivalent dielectric constant can be obtained by forming a high-k film to a thickness of 4.5 nm by using HfO₂. In this way, mainly for the capacitors of a direct random access memory (DRAM), high-k films such as HfO₂ and ZrO₂ films can be used as insulating films. As a method of forming a high-k film, there is an atomic layer deposition (ALD) method that has good concave part filling characteristics and step coverage.

In a HfO₂ or ZrO₂ film forming process, an amide compound such as tetra ethyl methyl amino hafnium (TEMAH: Hf[N(CH₃)(C₂H₅)]₄) or tetra ethyl methyl amino zirconium (TEMAZ: Zr[N(CH₃)(C₂H₅)]₄) is widely used as a metal source. Vapor (H₂O) or ozone (O₃) is used as an oxidant. In an ALD film forming method, a metal source such as TEMAH or TEMAZ, and an oxidant such as ozone (O₃) are alternately supplied to a reaction chamber so as to form a film.

[Patent Document 1] Japanese Unexamined Patent Application Publication No. 2005-259966

[Patent Document 2] Japanese Unexamined Patent Application Publication No. 2006-66587

However, in a method of forming a metal oxide film at a low temperature by using an ALD method, for example, if a HfO₂ film is formed in a state where O₃ (oxidant) is not sufficiently activated, a desired film forming rate cannot be obtained, and other problems are caused: for example, the thickness of a HfO₂ film is reduced at the center part of a pattern wafer having a trench structure to result in poor step coverage, or the coverage characteristics of HfO₂ films are deteriorated according to the number of pattern wafers charged as a batch, or the thickness of a HfO₂ film is varied according to the density of a pattern (this phenomenon is called “loading effect”).

If the supply amount or time of ozone (oxidant) is increased so as to increase the film forming rate or improve the step coverage or loading effect, although the step coverage or the loading effect can be improved owing to the increased film forming rate, since the film forming time is increased, throughput is decreased or raw material consumption is increased, and thus cost of ownership (COO: manufacturing costs per wafer) is increased. Examples of the related art are disclosed in Patent Documents 1 and 2.

### SUMMARY OF THE INVENTION

An object of the present invention is to provide a method of manufacturing a semiconductor device and a substrate processing apparatus that can be used to form an oxide film with improved coverage characteristics and loading effect without having to increase the supply amount or time of an oxidant.

According to an aspect of the present invention, there is provided a method of manufacturing a semiconductor device, the method comprising: loading at least one substrate to a processing chamber; forming an oxide film on the substrate by alternately supplying a first reaction material and a second reaction material containing oxygen atoms to the processing chamber while heating the substrate; and unloading the substrate from the processing chamber, wherein the forming of the oxide film is performed by keeping the substrate at a temperature lower than a self-decomposition temperature of the first reaction material and irradiating ultraviolet light to the second reaction material.

According to another aspect of the present invention, there is provided a substrate processing apparatus comprising: a processing chamber in which a substrate is accommodated; a heating unit configured to heat the substrate; a first gas supply unit configured to supply a first reaction material to the processing chamber; a second gas supply unit configured to supply a second reaction material containing oxygen atoms to the processing chamber; an exhaust unit configured to exhaust an inside atmosphere of the processing chamber; and a control unit configured to control at least the heating unit, the first gas supply unit, and the second gas supply unit, wherein the second gas supply unit comprises an ultraviolet generating mechanism configured to irradiate ultraviolet light to the second reaction material for activating the second reaction material, and the control unit is configured to control the first gas supply unit, the second gas supply unit, the heating unit, the exhaust unit, and the ultraviolet generating mechanism, so as to form an oxide film on the substrate by alternately supplying the first reaction material and the second reaction material activated by the ultraviolet generating mechanism to the substrate while heating the substrate at a temperature equal to or lower than a self-decomposition temperature of the first reaction material.

### BRIEF DESCRIPTION OF THE DRAWINGS

FIG. 1 is a view for schematically explaining adsorption of an oxide film source material on the surface of a Si substrate and oxidation of ozone according to a preferred embodiment of the present invention.

FIG. 2 is a view for schematically explaining temperature dependency of O₃ concentration according a preferred embodiment of the present invention.

FIG. 3 is a perspective view schematically illustrating a semiconductor device manufacturing apparatus according to a preferred embodiment of the present invention.

FIG. 4 is a side perspective view schematically illustrating a semiconductor device manufacturing apparatus according to a preferred embodiment of the present invention.

FIG. 5 is a vertical sectional view of a process furnace for schematically illustrating the process furnace and accompanying members according to a preferred embodiment of the present invention.

FIG. 6 is a sectional view taken along line A-A of FIG. 5 for explaining Embodiment 1 of the present invention.

FIG. 7 is a vertical sectional schematically illustrating the process furnace and surrounding structures of the process furnace according to a preferred embodiment of the present invention.

FIG. 8 is a partial sectional view schematically illustrating a nozzle configured to supply O₃ according to a preferred embodiment of the present invention.

FIG. 9 is a sectional view taken along line B-B of FIG. 8.

FIG. 10 is a view for schematically explaining processes of a semiconductor device manufacturing method according to a preferred embodiment of the present invention.

FIG. 11 is a sectional view taken along line A-A of FIG. 5 for explaining Embodiment 2 of the present invention.

FIG. 12 is a partial sectional view schematically illustrating a nozzle configured to supply O₃ according to Embodiment 3 of the present invention.

FIG. 13 is a sectional view taken along line C-C of FIG. 12.

FIG. 14 is a graph illustrating a relationship between potential energy and internuclear distance of oxygen.

### DETAILED DESCRIPTION OF THE PREFERRED EMBODIMENTS

Preferable embodiments of the present invention will be described hereinafter with reference to the attached drawings.

[Film Forming Principle]

First, the principle of forming a film will now be explained by taking, as an example, the process of forming a HfO₂ film (metal oxide film) by an atomic layer deposition (ALD) method using tetra ethyl methyl amino hafnium (TEMAH) and ozone (O₃).

Thermal decomposition of TEMAH and O₃ introduced into a processing chamber is as follows.

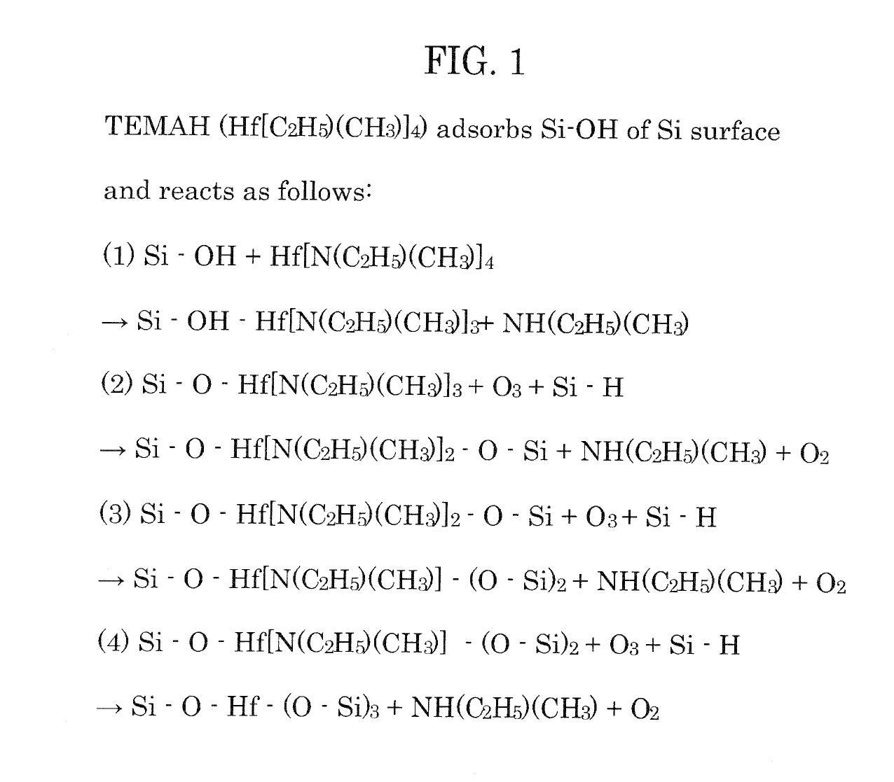

As shown in FIG. 1, Si—H and Si—OH bonds exist on a Si substrate. When TEMAH is introduced into a processing chamber, as expressed by Formula (1) of FIG. 1, the TEMAH adsorbs on the Si—H bonds, and ethyl methyl amine (N(C₂H₅)(CH₃)) is discharged.

Next, O₃ is supplied to the inside of the processing chamber. Then, as expressed by Formula (2) of FIG. 1, more ethyl methyl amine (N(C₂H₅)(CH₃)) is discharged from the TEMAH, and Hf—O—Si bonds are generated. If O₃ is further supplied, as expressed by Formulas (3) and (4) of FIG. 1, Si—O—Hf[N(C₂H₅)(CH₃)]—(O—Si)₂ and Si—O—Hf—(O—Si)₃ bonds are generated. That is, in the initial stage, Hf molecules emit ethyl methyl amine (N(C₂H₅)(CH₃)) and couples to Si of the substrate so as to form Hf—O—Si sequentially.

Here, the thermal decomposition of O₃ used as an oxidant can be expressed by Formulas 1 and 2 proposed by S. W. Benson and A. E. Axworthy Jr (refer to “Ozone Handbook” published by Japan ozone association).

$$\begin{matrix}[ Formula 1 ] & \\ {O}_{3} + M {{\to }^{{k}_{1}}}_{{←}_{{k}_{2}}} {O}^{*} + {O}_{2} + M & ( 1 ) \\ [ Formula 2 ] & \\ {O}^{*} + {O}_{3} {\to }^{{k}_{3}} {O}_{2} + {O}_{2} & ( 2 )\end{matrix}$$

In Formula 1, M denotes a third substance such as N₂, O₂, CO₂, and O₃. Formulas 1 and 2 can be expressed by Formula 3 below.

$$\begin{matrix}[ Formula 3 ] & \\ \frac{1}{{[ {O}_{3} ]}_{t}} = \frac{2 {k}_{1} {k}_{3}}{{k}_{2} [ {O}_{2} ]} t \frac{1}{{[ {O}_{3} ]}_{a}} & ( 3 )\end{matrix}$$

In Formula 3, [O₃]ₜ denotes the concentration of ozone after time (t), [O₂] denotes the concentration of oxygen, [O₃]_{S} denotes the initial concentration of ozone, and (t) denotes time.

In Formulas 1 and 2, k₁, k₂, and k₃ are expressed by Formula 4, 5, and 6.

k₁=(4.61±0.25)×1015exp(−24000/RT) cm3/mols−1 (If M=O₃) (4)

k₂=(6.00±0.33)×1015exp(+600/RT) cm3/mols−1 (5)

k₃=(2.96±0.21)×1015exp(−6000/RT) cm3/mols−1 (6)

Ozone radicals (O*) participate in reaction. In the case where O* is supplied to Si substrates arranged in multiple stages in a batch type film forming apparatus, if the amount of O* is insufficient, reaction with TEMAH does not proceed sufficiently. Therefore, for example, sufficient film forming rate may not be ensured, or characteristics of step coverage or loading effect may be degraded at the center parts of the Si substrates. Referring to Formulas 1 and 3, to increase the amount of O*, it is necessary to increase the flowrate of O₃ supplied to a processing chamber, increase the temperature of O₃ gas, or irradiate ultraviolet light.

Preferred embodiments of the present invention provide methods for effectively increasing the concentration of O₃ as compared with conventional O₃ supply methods.

### Embodiment 1

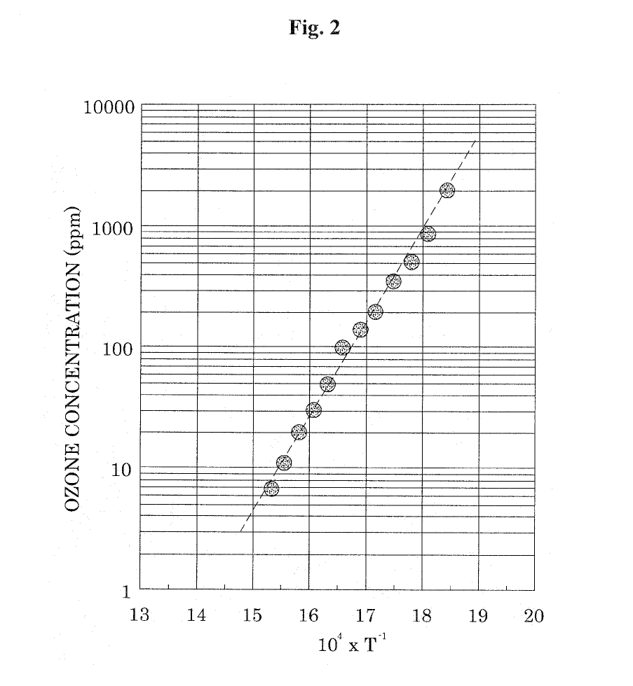

As shown in FIG. 2, the concentration of O₃ in gas decreases as temperature increases.

For example, O₃ is heated from the state of O₃/O₂ 17000 ppm, the concentration of O₃ becomes about 350 ppm at 300° C. and changes to about 4 ppm at 400° C. That is, the concentration of O₃ decreases to about 1/70 to 1/80 the initial value when the temperature increases by 100° C. from 300° C. to 400° C.

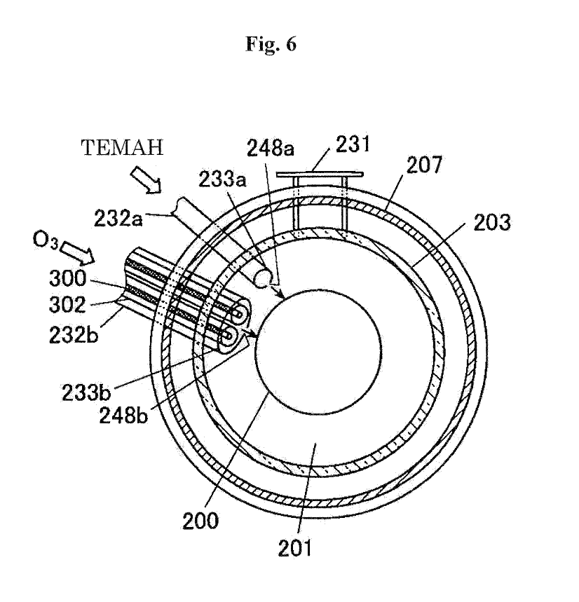

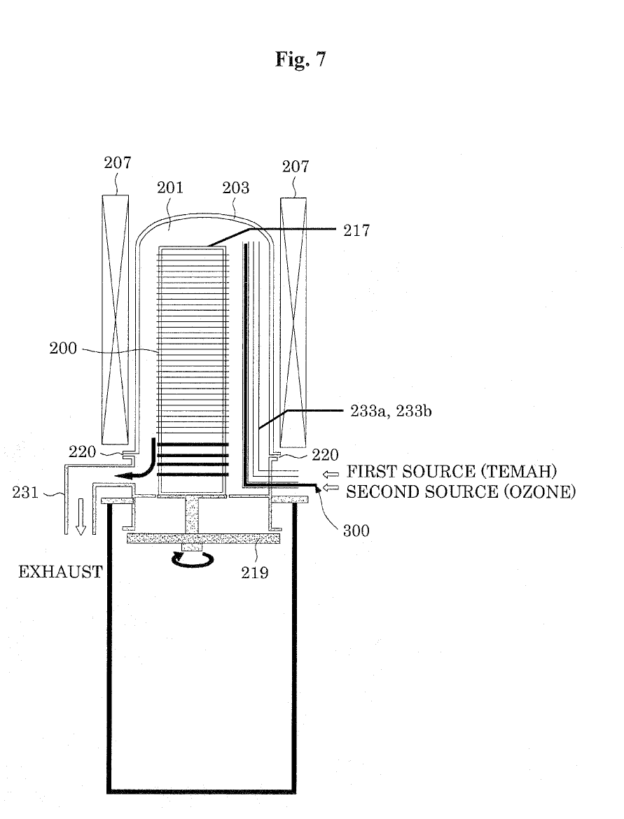

As shown in Formula 1, when the concentration of O₃ decreases, 1 mole of O* generates as a result of decomposition of 1 mole of O₃. That is, the amount of O* can be increased by about 70 to 80 times by increasing the temperature from 300° C. to 400° C. However, the concentration of generated O* decreases due to reverse reaction with O₂ as shown by the reverse direction in Formula 1 or reaction with O₃ as shown by Formula 2. To prevent this reaction, it is necessary to generate O* in the vicinity of a Si substrate. For this, according to a preferred embodiment of the present invention, a heater is installed at the inside of a nozzle through which O₃ is supplied to a processing chamber, and when O₃ is supplied, the O₃ is heated by using the heater (described later with reference to FIG. 6, and FIG. 7 to FIG. 9).

[Overall Structure of Apparatus]

Based on the above description in [Film forming principle], an apparatus and method for manufacturing a semiconductor device will now be described in detail according to preferred embodiments of the present invention.

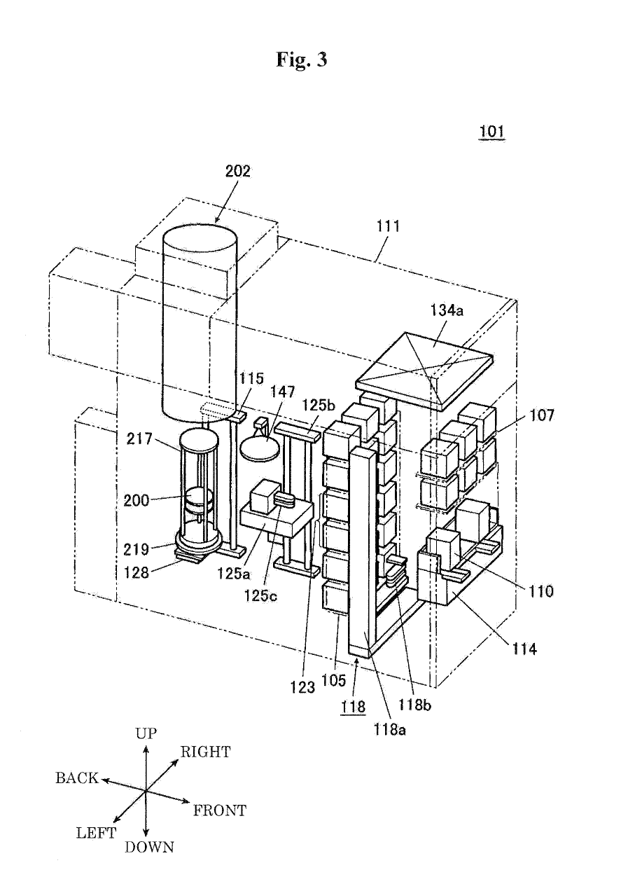

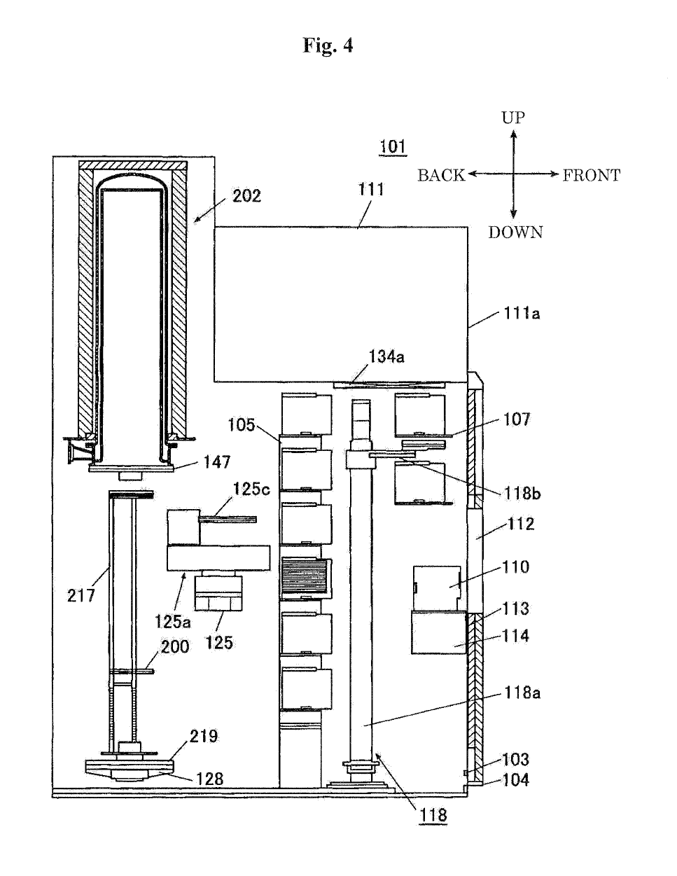

First, with reference to FIG. 3 and FIG. 4, an explanation will be given on a semiconductor device manufacturing apparatus that is used in a processing process of a semiconductor device manufacturing method according to a preferred embodiment of the present invention.

As shown in FIGS. 3 and 4, in a semiconductor device manufacturing apparatus 101, cassettes 110 are used as wafer carriers to accommodate wafers 200 made of a material such as silicon.

The semiconductor device manufacturing apparatus 101 includes a housing 111. At the lower side of a front wall 111a, an opening is formed as a front maintenance port 103 for maintenance works. At the front maintenance port 103, a front maintenance door 104 that can be opened and closed is installed.

At the front maintenance door 104, a cassette carrying port 112 is installed so that the inside of the housing 111 can communicate with the outside of the housing 111 through the cassette carrying port 112, and the cassette carrying port 112 can be opened and closed by using a front shutter 113.

At a side of the cassette carrying port 112 located inside the housing 111, a cassette stage 114 is installed. A cassette 110 is carried on the cassette stage 114 or away from the cassette stage 114 by an in-plant carrying device (not shown).

A cassette 110 is placed on the cassette stage 114 by the in-plant carrying device in a state where wafers 200 are vertically positioned inside the cassette 110 and a wafer port of the cassette 110 faces upward. The cassette stage 114 is configured so that the cassette 110 is rotated 90° counterclockwise in a longitudinal direction to the backward of the housing 111, and the wafers 200 inside the cassette 110 take a horizontal position, and the wafer port of the cassette 110 faces the backward of the housing 111.

Near the center part of the housing 111 in a front-to-back direction, a cassette shelf 105 is installed. The cassette shelf 105 is configured so that a plurality of the cassettes 110 are stored in a plurality of stages and a plurality of rows. At the cassette shelf 105, a transfer shelf 123 is installed to store the cassettes 110, which are carrying objects of a wafer transfer mechanism 125. In addition, at the upside of the cassette stage 114, a standby cassette shelf 107 is installed to store standby cassettes 110.

Between the cassette stage 114 and the cassette shelf 105, a cassette carrying device 118 is installed. The cassette carrying device 118 is configured by a cassette elevator 118a which is capable of moving upward and downward while holding a cassette 110, and a cassette carrying mechanism 118b. The cassette carrying device 118 is designed to carry cassettes 110 among the cassette stage 114, the cassette shelf 105, and the standby cassette shelf 107 by continuous motions of the cassette elevator 118a and the cassette carrying mechanism 118b.

At the backside of the cassette shelf 105, the wafer transfer mechanism 125 is installed. The wafer transfer mechanism 125 is configured by a wafer transfer device 125a that is capable of rotating or linearly moving a wafer 200 in a horizontal direction, and a wafer transfer device elevator 125b configured to move the wafer transfer device 125a upward and downward. The wafer transfer device elevator 125b is installed at a right end part of the housing 111 (pressure-resistant housing). The wafer transfer mechanism 125 is configured such that a wafer 200 can be picked up with tweezers 125c of the wafer transfer device 125a by continuous motions of the wafer transfer device 125a and the wafer transfer device elevator 125b so as to charge the wafer 200 into a boat 217 or discharge the wafer 200 from the boat 217.

As shown in FIG. 3 and FIG. 4, at the upside of the rear part of the housing 111, a process furnace 202 is installed. The bottom side of the process furnace 202 is configured to be opened and closed by a furnace port shutter 147.

At the downside of the process furnace 202, a boat elevator 115 is installed to move the boat 217 upward to and downward from the process furnace 202. An arm 128 is connected to the boat elevator 115 as a connecting unit, and a seal cap 219 is horizontally installed on the arm 128 as a cover. The seal cap 219 supports the boat 217 vertically and is configured to close the bottom side of the process furnace 202.

The boat 217 includes a plurality of holding members and is configured to hold a plurality of wafers 200 (for example, about fifty to one hundred fifty wafers 200) horizontally in astute where the centers of the wafers 200 are aligned and arranged in a vertical direction.

As shown in FIGS. 3 and 4, at the upside of the cassette shelf 105, a cleaning unit 134a is installed to supply clean air as purified atmosphere. The cleaning unit 134a includes a supply fan and a dust filter and is configured to supply clean air to the inside of the housing 111.

At the left side end part of the housing 111 opposite to the wafer transfer device elevator 125b and the boat elevator 115, another cleaning unit (not shown) is installed to supply clean air. Like the cleaning unit 134a, the cleaning unit includes a supply fan and a dust filter. Clean air supplied through the cleaning unit flows in the vicinities of the wafer transfer device 125a and the boat 217 and is exhausted to the outside of the housing 111.

Next, an operation of the semiconductor device manufacturing apparatus 101 will be described.

As shown in FIG. 3 and FIG. 4, before a cassette 110 is carried onto the cassette stage 114, the front shutter 113 is moved to open the cassette carrying port 112. Thereafter, the cassette 110 is placed on the cassette stage 114 through the cassette carrying port 112. At this time, wafers 200 accommodated inside the cassette 110 are vertically positioned, and the wafer port of the cassette 110 faces upward.

Next, the cassette 110 is rotated counterclockwise by 90° in a longitudinal direction toward the backward of the housing 111 by the cassette stage 114 so that the wafers 200 inside the cassette 110 are horizontally positioned and the wafer carrying port of the cassette 110 faces the backside of the housing 111.

After that, the cassette 110 is automatically carried and placed by the cassette carrying device 118 to a specified position of the cassette shelf 105 or the standby cassette shelf 107 so as to be temporarily stored, and then transferred to the transfer shelf 123 from the cassette shelf 105 or the standby cassette shelf 107 by the cassette carrying device 118, or the cassette 110 is directly transferred to the transfer shelf 123.

After the cassette 110 is transferred to the transfer shelf 123, a wafer 200 is picked up from the cassette 110 through the wafer port of the cassette 110 by the tweezers 125c of the wafer transfer device 125a and is charged into the boat 217 disposed at the backside of a transfer chamber 124. After the wafer transfer device 125a delivers the wafer 200 to the boat 217, the wafer transfer device 125a returns to the cassette 110 so as to charge the next wafer 200 to the boat 217.

After a predetermined number of wafers 200 are charged into the boat 217, the bottom side of the process furnace 202 closed by the furnace port shutter 147 is opened by moving the furnace port shutter 147. Subsequently, the boat 217 holding the wafers 200 is loaded into the process furnace 202 by lifting the seal cap 219 using the boat elevator 115.

After the loading, a predetermined treatment is performed on the wafers 200 disposed inside the process furnace 202. Thereafter, the wafers 200 and the cassette 110 are carried to the outside of the housing 111 in the reverse sequence of the above.

[Structure of Process Furnace]

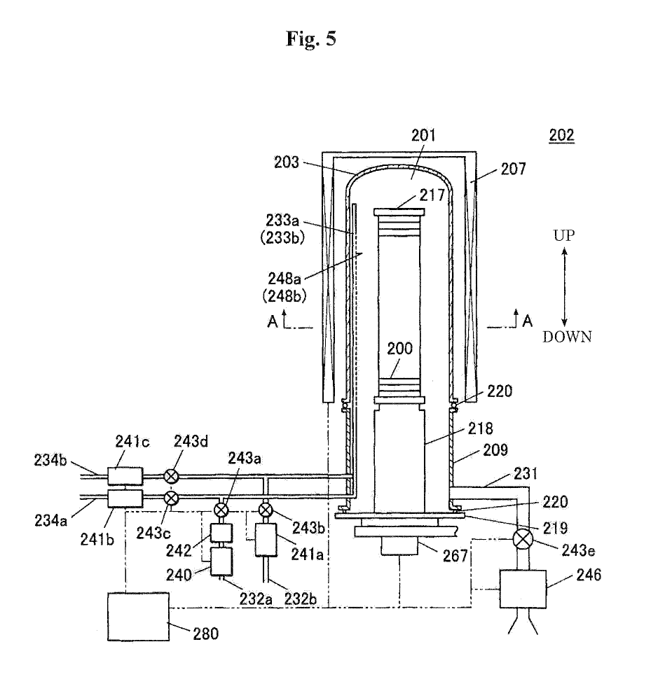

As shown in FIG. 5, a heater 207 is installed at the process furnace 202 as a heating unit. Inside the heater 207, a reaction tube 203 is installed, which is capable of accommodate substrates such as wafers 200. The reaction tube 203 is made of quartz. At the bottom side of the reaction tube 203, a manifold 209 made of a material such as stainless steel is installed. At the bottom side of the reaction tube 203 and the top side of the manifold 209, ring-shaped flanges are respectively formed.

An O-ring 220 is installed between the flanges of the reaction tube 203 and the manifold 209, and the joint between the reaction tube 203 and the manifold 209 is air-tightly sealed. The bottom side of the manifold 209 is air-tightly closed by the seal cap 219 (cover) with an O-ring 220 being disposed therebetween. At the process furnace 202, a processing chamber 201 is formed by at least the reaction tube 203, the manifold 209, and the seal cap 219 so as to process wafers 200.

At the seal cap 219, the boat 217 that is a substrate holding member is installed with a boat support stand 218 being disposed between the seal cap 219 and the boat 217. The boat support stand 218 is a holding body which is used to hold the boat 217. The boat 217 is disposed approximately at the center of the reaction tube 203 in a state where the boat 217 is supported on the boat support stand 218. At the boat 217, a plurality of wafers 200 to be batch processed are held in a horizontal position and are piled in multiple stages in the vertical direction of FIG. 5. The heater 207 is used to heat the wafers 200 placed inside the processing chamber 201 to a predetermined temperature.

The boat 217 is configured to be lifted and lowered in the vertical direction of FIG. 5 by the boat elevator 115 (refer to FIG. 3) so that the boat 217 can be loaded into and unloaded from (lifted into and lowered away from) the reaction tube 203. Under the boat 217, a boat rotating mechanism 267 is installed to rotate the boat 217 for improving processing uniformity. That is, the boat 217 held on the boat support stand 218 can be rotated by using the boat rotating mechanism 267.

Two gas supply pipes 232a and 232b are connected to the processing chamber 201 for supplying two kinds of gases.

At the gas supply pipe 232a, a flowrate control device such as a liquid mass flow controller 240, a vaporizer 242, and an on-off valve such as a valve 243a are installed sequentially from the upstream side of the gas supply pipe 232a. A carrier gas supply pipe 234a used to supply carrier gas is connected to the gas supply pipe 232a. At the carrier gas supply pipe 234a, a flowrate control device such as a mass flow controller 241b and an on-off valve such as a valve 243c are installed sequentially from the upstream side of the carrier gas supply pipe 234a.

An end part of the gas supply pipe 232a is connected to a nozzle 233a made of quartz. The nozzle 233a extends vertically in an arc-shaped space between the wafers 200 and the inner wall of the reaction tube 203 constituting the processing chamber 201 as shown in FIG. 5. A plurality of gas supply holes 248a are formed in the lateral surface of the nozzle 233a. The gas supply holes 248a have the same size and are arranged with the same pitch from the downside to the upside of the nozzle 233a.

At the gas supply pipe 232b, a flowrate control device such as a mass flow controller 241a and an on-off valve such as a valve 243b are installed sequentially from the upstream side of the gas supply pipe 232b. A carrier gas supply pipe 234b used to supply carrier gas is connected to the gas supply pipe 232b. At the carrier gas supply pipe 234b, a flowrate control device such as a mass flow controller 241c and an on-off valve such as a valve 243d are installed sequentially from the upstream side of the carrier gas supply pipe 234a.

An end part of the gas supply pipe 232b is connected to a nozzle 233b made of quartz. The nozzle 233b extends vertically in the arc-shaped space between the wafers 200 and the inner wall of the reaction tube 203 constituting the processing chamber 201 as shown in FIG. 5. A plurality of gas supply holes 248b are formed in the lateral surface of the nozzle 233b. The gas supply holes 248b have the same size and are arranged with the same pitch from the downside to the upside of the nozzle 233b.

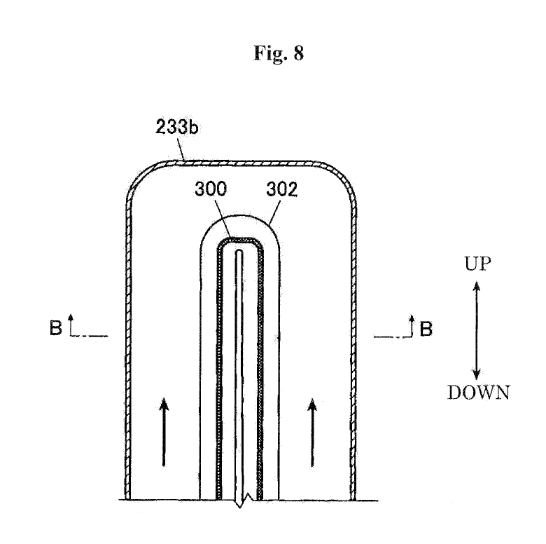

As shown in FIG. 6 to FIG. 9, inside the nozzle 233b, a heater 300 (heater wire) is installed to heat gas flowing through the nozzle 233b. As shown in FIG. 6, the heater 300 extends from the end part of the gas supply pipe 232a and penetrates the nozzle 233b. As shown in FIG. 7, the heater 300 extends vertically in a space between the inner wall of the reaction tube 203 and the boat 217. Particularly, as shown in FIG. 8, the heater 300 is folded backward at the top part of the nozzle 233b.

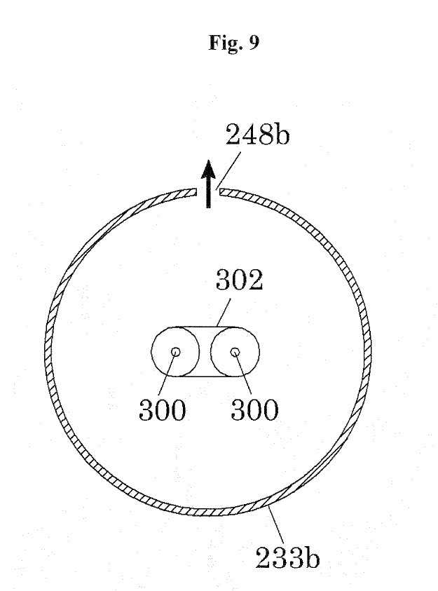

As shown in FIG. 6, FIG. 8, and FIG. 9, the heater 300 is covered with a protection pipe 302 made of quartz. The protection pipe 302 has a reversed U-shape along the backwardly folded part of the heater 300 (refer to FIG. 8) so as to cover the heater 300 completely. In the current embodiment, it is configured such that when gas is introduced into the nozzle 233b, the gas is heated by the heater 300 and supplied to the processing chamber 201 through the gas supply holes 248b.

As shown in FIG. 5, an end part of a gas exhaust pipe 231 is connected to the processing chamber 201 so as to exhaust the inside atmosphere of the processing chamber 201. The other end part of the gas exhaust pipe 231 is connected to a vacuum pump 246 so that the inside of the processing chamber 201 can be evacuated. At the gas exhaust pipe 231, a valve 243e is installed. The valve 243e is an on-off valve which is configured to be opened and closed so as to start and stop evacuation of the processing chamber 201, and configured to be adjusted in opening size for controlling the pressure inside the processing chamber 201.

A controller 280, which is a control unit, is connected to members such as the liquid mass flow controller 240, the mass flow controllers 241a to 241c, the valves 243a to 243e, the heaters 207 and 300, the vacuum pump 246, the boat rotating mechanism 267, and the boat elevator 115.

The controller 280 controls operations such as the flowrate adjusting operation of the liquid mass flow controller 240; the flowrate adjusting operations of the mass flow controllers 241a to 241c; the opening and closing operations of the valves 243a to 243d; the opening, closing, and pressure adjusting operations of the valves 243e; the temperature adjusting operations of the heaters 207 and 300; the start and stop operations of the vacuum pump 246; the rotation speed adjusting operation of the boat rotating mechanism 267; and the elevating operation of the boat elevator 115.

[Method of Manufacturing Semiconductor Device]

Next, a method of forming a film using the process furnace 202 will now be explained as an example of a method of manufacturing a semiconductor device according to a preferred embodiment of the present invention.

In the process furnace 202, high dielectric constant films (high-k films) such as SiO₂, HfO₂, and ZrO₂ films can be formed on wafers 200.

As a reaction material (film forming material), TDMAS may be used to form a SiO₂ film. A HfO₂ film may be formed by using reaction materials such as tetrakis ethyl methyl amino hafnium (TEMAH, Hf(NEtMe)₄), Hf(O-tBu)₄, tetrakis dimethyl amino hafnium (TDMAH, Hf(NMe₂)₄), tetrakis diethyl amino hafnium (TDEAH, Hf(NEt₂)₄), and Hf(MMP)₄. Similar to the case of forming a HfO₂, a ZrO₂ may be formed by using reaction materials such as Zr(NEtMe)₄, Zr(O-tBu)₄, Zr(NMe₂)₄), Zr(NEt₂)₄), and Zr(MMP)₄. In the above mentioned chemical formulas,

┌Et┘ denotes C₂H₅, ┌Me┘ denotes CH₃, ┌O-tBu┘ denotes OC(CH₃)₃, and ┌MMP┘ denotes OC(CH₃)₂CH₂OCH₃.

As another reaction material, O₃ may be used.

In the current embodiment, as an example of a film forming process using an ALD method, a process of forming a film on a wafer 200 by using TEMAH and O₃ as reaction materials will now be explained.

In an ALD (atomic layer deposition) method, process gases which provide at least two source materials for forming a film are sequentially supplied to a substrate one after another under predetermined film forming conditions (temperature, time, etc.), so as to allow the process gases to be adsorbed on the substrate on an atomic layer basis for forming a film by a surface reaction. At this time, the thickness of the film can be controlled by adjusting the number of process gas supply cycles (for example, if the film forming rate is 1 Å/cycle and it is intended to form a 20-Å film, the process is repeated 20 cycles.

For example, in the case where a HfO₂ film is formed by an ALD method, high-quality film formation is possible at a low temperature range from 180° C. to 300° C. by using TEMAH and O₃.

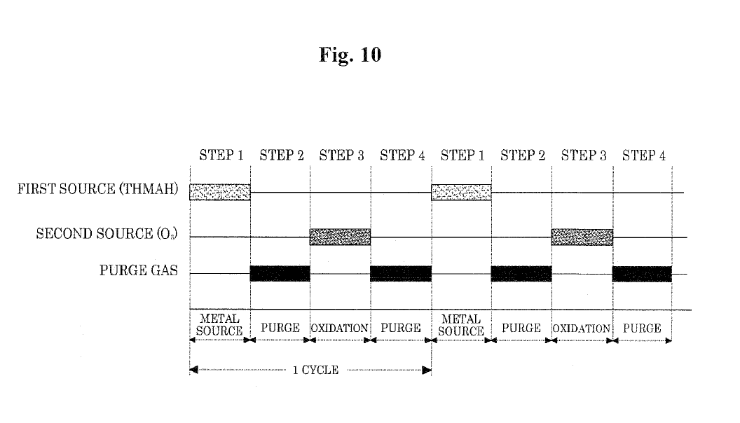

First, as described above, wafers 200 are charged into the boat 217, and the boat 217 is loaded into the processing chamber 201. After the boat 217 is loaded into the processing chamber 201, the following steps 1 to 4 are sequentially performed. The steps 1 to 4 are repeated until HfO₂ films are formed to a predetermined thickness (refer to FIG. 10).

(Step 1)

TEMAH is allowed to flow through the gas supply pipe 232a, and carrier gas is allowed to flow through the carrier gas supply pipe 234a. Gas such as helium (He), neon (Ne), argon (Ar), and nitrogen (N₂) may be used as carrier gas. Particularly, in the current embodiment, N₂ is used as carrier gas. The valve 243a of the gas supply pipe 232a is opened.

TEMAH flows through the gas supply pipe 232a while the flowrate of the TEMAH is controlled by the liquid mass flow controller 240, and the TEMAH is vaporized at the vaporizer 242. The vaporized TEMAH is introduced into the nozzle 233a from the gas supply pipe 232a, and then, the vaporized TEMAH is supplied to the inside of the processing chamber 201 through the gas supply holes 248a and is exhausted through the gas exhaust pipe 231.

At this time, the inside pressure of the processing chamber 201 is kept in the range from 26 Pa to 266 Pa, for example, 66 Pa, by properly adjusting the valve 243e of the gas exhaust pipe 231. In addition, the temperature of the wafers 200 is adjusted in the range from 180° C. to 300° C., for example, 200° C., by controlling the heater 207.

In Step 1, vaporized TEMAH is supplied to the processing chamber 201 and adsorbed on the surfaces of the wafers 200.

(Step 2)

The valve 243a of the gas supply pipe 232a is closed so as to interrupt supply of TEMAH. At this time, the valve 243e of the gas exhaust pipe 231 is kept open, and the inside of the processing chamber 201 is exhausted to a pressure equal to or lower than 20 Pa by using the vacuum pump 246 so as to exhaust vaporized TEMAH remaining in the processing chamber 201.

After the inside of the processing chamber 201 is exhausted for a predetermined time, in a state where the valve 243a of the gas supply pipe 232a is closed, the valve 243c of the carrier gas supply pipe 234a is opened. Carrier gas of which the flowrate is controlled by the mass flow controller 241b is supplied to the inside of the processing chamber 201 so as to replace the inside atmosphere of the processing chamber 201 with N₂.

(Step 3)

O₃ gas is allowed to flow through the gas supply pipe 232b, and carrier gas is allowed to flow through the carrier gas supply pipe 234b. Gas such as helium (He), neon (Ne), argon (Ar), and nitrogen (N₂) may be used as carrier gas. Particularly, in the current embodiment, N₂ is used as carrier gas. The valve 243b of the gas supply pipe 232b, and the valve 243d of the carrier gas supply pipe 234b are opened.

Carrier gas flows through the carrier gas supply pipe 234b while the flowrate of the carrier gas is controlled by mass flow controller 241c, and the carrier gas is introduced into the gas supply pipe 232b from the carrier gas supply pipe 234b. O₃ gas flows through the gas supply pipe 232b while the flowrate of the O₃ gas is controlled by the mass flow controller 241a, and the O₃ gas is mixed with the carrier gas while flowing through the gas supply pipe 232b. In the state where the O₃ gas is mixed with the carrier gas, the O₃ gas is introduced into the nozzle 233b from the gas supply pipe 232b, and the O₃ gas flows through the inner space of the nozzle 233b between the inner wall of the nozzle 233b and the protection pipe 302. Then, the O₃ gas is supplied to the processing chamber 201 through the gas supply holes 248b and is exhausted through the gas exhaust pipe 231.

At this time, the inside pressure of the processing chamber 201 is kept in the range from 26 Pa to 266 Pa, for example, 66 Pa, by properly adjusting the valve 243e of the gas exhaust pipe 231. The wafers 200 are exposed to O₃ for about 10 seconds to 120 seconds. Like the case where vaporized TEMAH is supplied in Step 1, the temperature of the wafers 200 is adjusted in the range from 180° C. to 300° C., for example, 200° C., by controlling the heater 207.

In Step 3, O₃ is heated inside the nozzle 233b to a temperature different from a control temperature of the inside of the processing chamber 201 in Step 1 (where TEMAH is supplied) and a control temperature of the inside of the processing chamber 201 in Step 3. That is, O₃ is heated inside the nozzle 233b to a temperature higher than the control temperatures. For example, if the inside of the processing chamber 201 is kept at 200° C. by controlling the heater 207, the temperature of the nozzle 233b is kept in the range from 300° C. to 400° C. by controlling the heater 300.

As explained in [Film forming principle], the reason for this is that decomposition of O₃ is dependent on temperature: that is, if the inside temperature of the processing chamber 201 is low, O₃ does not decompose sufficiently, and thus, ozone radicals are insufficiently supplied. Therefore, in Step 3, O₃ is heated inside the nozzle 233b to a high temperature, so as to supply ozone radicals to the wafers 200 sufficiently.

In Step 3, O₃ is supplied to the processing chamber 201 for reaction with TEMAH that is already adsorbed on surfaces of the wafers 200, so that if HfO₂ films can be formed.

(Step 4)

The valve 243b of the gas supply pipe 232b is closed to interrupt supply of O₃. At this time, the valve 243e of the gas exhaust pipe 231 is kept open, and the inside of the processing chamber 201 is exhausted to a pressure equal to or lower than 20 Pa by using the vacuum pump 246 so as to exhaust O₃ remaining in the processing chamber 201.

After the inside of the processing chamber 201 is exhausted for a predetermined time, in a state where the valve 243b of the gas supply pipe 232b is closed, the valve 243d of the carrier gas supply pipe 234b is opened. Carrier gas of which the flowrate is controlled by the mass flow controller 241c is supplied to the inside of the processing chamber 201 so as to replace the inside atmosphere of the processing chamber 201 with N₂.

In the current embodiment, the heater 300 is installed in the nozzle 233b, and in Step 3, O₃ is supplied to wafers 200 after the O₃ is heated by using the heater 300 to a temperature higher than the temperature of heated TEMAH and the inside temperature of the processing chamber 201. Therefore, it is considered that ozone radicals generated from the O₃ (ozone) can be supplied to the wafers 200 in an activated state. Thus, when HfO₂ films are formed, the coverage characteristics and loading effect of the HfO₂ films can be improved without increasing the amount or time of supply of O₃ functioning as an oxidant, and owing to this, decrease of throughput or increase of cost of ownership (COO) can be previously prevented.

In the current embodiment, the semiconductor device manufacturing method is explained for the case of forming HfO₂ films as metal oxide films. However, in other cases of using different reaction materials or forming different films, the inside temperature of the processing chamber 201 controlled by the heater 207 may be changed within the range of 20° C. to 600° C.: for example, if ZrO₂ films are formed by using TEMAZ and O₃, the inside temperature of the processing chamber 201 may be properly controlled within the range of 180° C. to 300° C., or the temperature of a reaction material (such as O₃ functioning as an oxidant) may be properly controlled by the heater 300 within the range from 20° C. to 600° C., preferably, within the range from 300° C. to 400° C.

The inside temperature of the processing chamber 201 is determined by the characteristics of a first source material. For example, TEMAH is used as a first source material, the self-decomposition temperature of the TEMAH measured by an accelerating rate calorimeter (ARC) or a sealed cell-differential scanning calorimeter (SC-DSC) is 271° C., and if the temperature of the TEMAH exceeds this temperature, the TEMAH starts to decompose rapidly. On the other hand, O₃ used as a second source material hardly decomposes at a temperature equal to or lower than 200° C. Therefore, for the system of TEMAH and O₃, processing chamber temperature is kept in the range of 200° C. to 250° C. If tris(dimethylamino) silane (TDMAS) is used as a first source material, self-decomposition temperature is 508° C. In the case where a SiO₂ film is formed by using the system of TDMAS and O₃, O₃ may decompose sufficiently in the temperature range from 300° C. to 500° C. However, if the film forming process is performed in a temperature equal to or lower than 300° C., like in the case of using TEMAH, the temperature of a reaction material such as O₃ functioning as an oxidant may be properly controlled by the heater 300 within the range from 20° C. to 600° C., preferably, within the range from 30° C. to 400° C.

### Embodiment 2

According to another embodiment of the present invention, an apparatus and method for manufacturing a semiconductor device will now be described in detail. A substrate processing apparatus 101 of Embodiment 2 is characteristically different, in that a mechanism configured to ultraviolet (UV) light is installed at a nozzle 233b instead of installing a heater 300 (heater wire) inside the nozzle 233b so as to heat a second reaction material such as O₃ functioning as an oxidant.

At the nozzle 233b, a light source is installed as an UV generating mechanism so as to excite gas flowing through the nozzle 233b. The light source may emit light having any wavelength within the UV region. For example, the light source may be a vacuum ultraviolet (VUV) lamp that emits VUV light having a wavelength such as 146 nm, 172 nm, and 183 nm; a UV lamp that emits UV light having a main wavelength such as 222 nm, 308 nm, 248 nm, and 258 nm; or a mercury lamp.

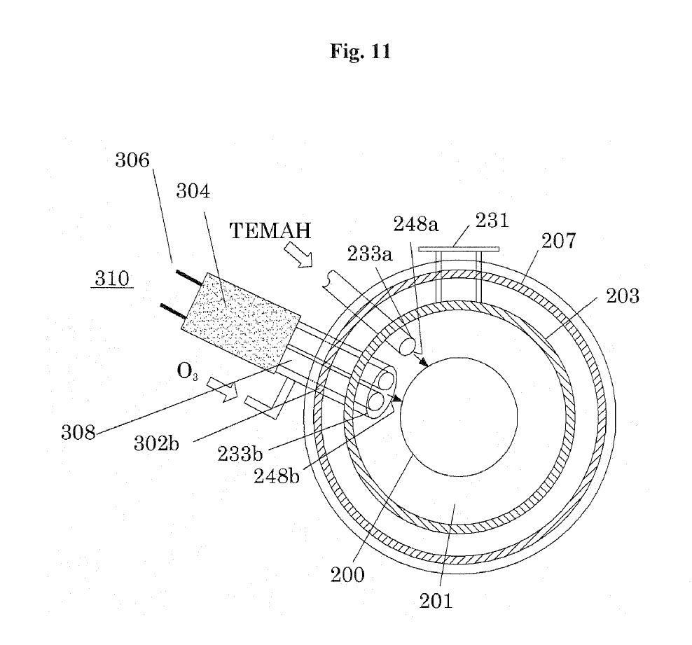

As shown in FIG. 11, according to Embodiment 2, a VUV lamp 310 is installed. The VUV lamp 310 includes a plasma excitation unit 304 installed at the inside of the nozzle 233b, and electrodes 306 are installed on the plasma excitation unit 304 so that a VUV discharge tube 308 can be turned on by applying high-frequency power to the electrodes 306. Gases such as Xe₂ and Kr₂ are filled in the VUV discharge tube 308 so that excimer light having wavelengths of 172 nm and 146 nm can be obtained.

The VUV lamp 310 and the electrodes 306 are connected to a control unit such as a controller 280, and the controller 280 performs a controlling operation such as supply of power.

O₃ flowing through the nozzle 233b is exposed to excimer light, and thus the O₃ is excited to one radicals (O*) and supplied in an excited state to wafers 200 disposed in a processing chamber 201.

### Embodiment 3

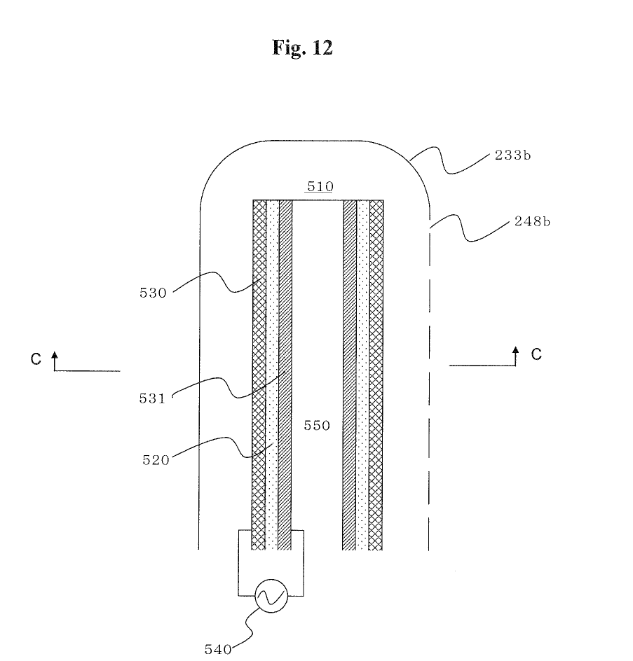

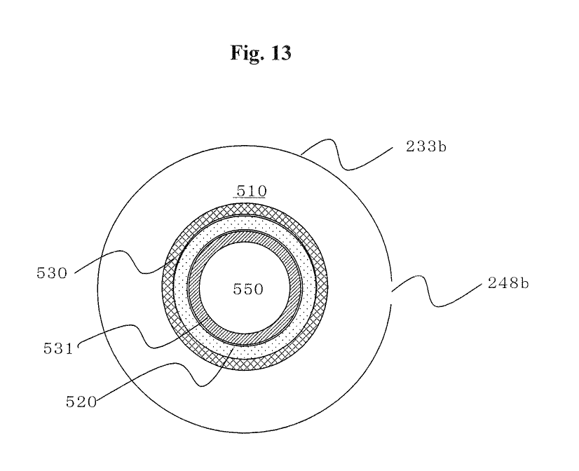

According to another embodiment using a mercury lamp or VUV lamp, a VUV lamp 510 can be installed in a nozzle 233b as shown in FIG. 12 and FIG. 13. Excimer is excited by silent discharge [dielectric barrier discharge].

The VUV lamp 510 includes a dielectric tube 520 made of a dielectric material such as quartz and having a hollow cylinder shape (dual structure), an outer electrode 530 installed outside the dielectric tube 520 and made of a metal having a net-like shape, and an inner electrode 531 installed inside the dielectric tube 520 and made of a metal. Discharge gas is filled in an inside area 550 of the dielectric tube 520 which is sealed. For example, Xe₂ gas is enclosed. In addition, a high-frequency power source 540 is connected to the outer electrode 530 and the inner electrode 531 so that dielectric barrier discharge can occur at many places in the shape of a narrow wire between two dielectrics (quartz gap) by applying high-frequency power across the two electrodes 530 and 531. High-energy electrons, which are contained in discharge plasma generated as described above, lose energy due to collision of atoms or molecules of discharge gas and thus disappear temporarily as expressed by Formula 7 below. Meanwhile, the discharge gas which receives energy from the electrons is excited, and as shown by Formula 8, the discharge gas collides with neutral atoms and becomes excimer state (Xe₂*) momentarily.

e+Xe→Xe* (7)

Xe*+2Xe→Xe₂*+Xe (8)

The excimer state is unstable, and during a transition to the ground state from the excimer state, energy is discharged in the form of excimer-spectrum light. As shown by Formula (9), the wavelength of excimer light of Xe gas is 172 nm.

Xe2*→Xe+Xe+hν(172ₙm) (9)

O₃ flowing through the nozzle 233b is exposed to excimer light, and thus the O₃ is excited to ozone radicals (O*) and supplied in an excited state to wafers 200 disposed in a processing chamber 201.

At the time when O₃ is supplied to the inside of the nozzle 233b, helium (He) may also be supplied to the inside of the nozzle 233b.

The VUV lamp 510, the outer electrode 530, the inner electrode 531, and the high-frequency power source 540 are connected to a control unit such as a controller 280, and the controller 280 performs a controlling operation such as supply of power.

The outer electrode 530 and the inner electrode 531 may not have a cylindrical shape but may have a shape for cover a part of the dielectric tube 520.

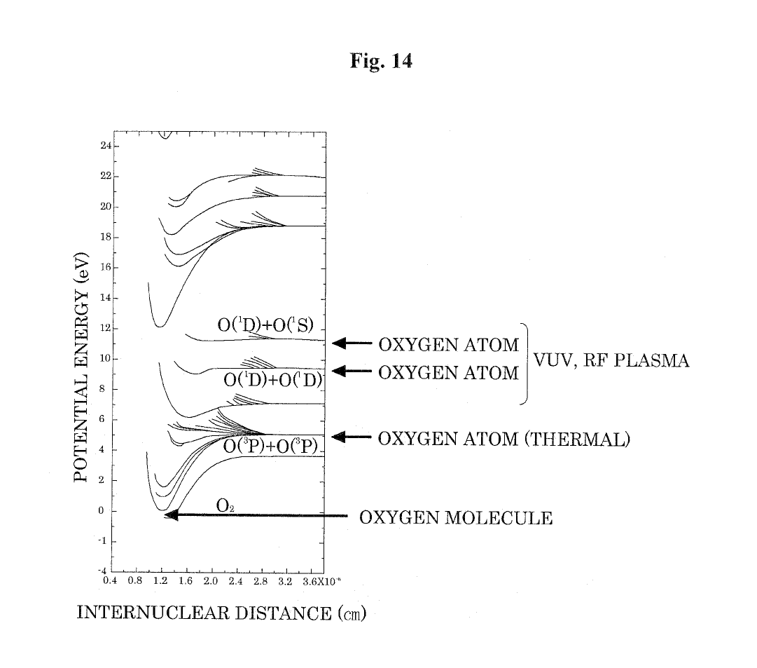

As shown in FIG. 14, as ground states of an oxygen radical, there are a triplet state O(³P) of which the energy level is higher than that of an oxygen molecule by 5.16 eV, and singlet states O(¹D) and O(¹S) of which the energy levels are much higher than that of an oxygen molecule. If potential energy is great, lifetime is short although oxidizing power is high. Potential energy by VUV is greater than potential energy by thermal dissociation of O₃, and oxidizing power by VUV is also greater than oxidizing power by thermal dissociation of O₃. As an oxidant that is activated by excitation, for example, O₂ or O₃ can be used. A proper oxidant is selected according to excitation energy.

By activating O₃ through VUV excitation as described in Embodiment 2 and Embodiment 3, sufficient O₃ radicals can be supplied to a wafer at a low temperature equal to or lower than 300° C.

In the case of using an organic compound such as TEMAH or TEMAZ, since a film forming process is performed at a low temperature in the range from 200° C. to 300° C., a HfO₂ or ZrO₂ film may be formed in a state where an oxidant such as O₃ is not sufficiently activated. In this case, a desired film forming rate may not be obtained, and in addition, the coverage characteristics of the oxide film may become poor or the loading effect may occur. However, according to Embodiment 2 or Embodiment 3, these problems can be solved without having to increase the amount or time of oxidant supply.

Furthermore, in Embodiment 3, a dual structure is provided by installing a flow passage around a light source to allow a flow of an oxidant such as O₂ or O₃, so that contamination of a barrier wall of the light source can be prevented during a film forming process.

According to the present invention, in an oxide film forming process, ultraviolet light is irradiated to a second reaction material functioning as an oxidant, so that the second reaction material can be supplied to a substrate in a state where the second reaction material is activated. Owing to this, when a metal oxide film is formed, without having to increase the supply amount or time of a second reaction material functioning as an oxidant, the growing rate of the metal oxide film can be increased to improve coverage characteristics or loading effect, and thus a decrease of throughput or an increase of COO can be previously prevented.

The present invention also includes the following embodiments.

(Supplementary Note 1)

According to a preferred embodiment of the present invention, there is provided a method of manufacturing a semiconductor device, the method comprising: loading at least one substrate to a processing chamber; forming an oxide film on the substrate by alternately supplying a first reaction material and a second reaction material containing oxygen atoms to the processing chamber while heating the substrate; and unloading the substrate from the processing chamber, wherein the forming of the oxide film is performed by keeping the substrate at a temperature lower than a self-decomposition temperature of the first reaction material and irradiating ultraviolet light to the second reaction material.

According to the semiconductor device manufacturing method, in the forming of the oxide film, ultraviolet light is irradiated to the second reaction material functioning as an oxidant, so that the second reaction material can be supplied to the substrate in a state where the second reaction material is activated. Owing to this, when the oxide film is formed, without having to increase the supply amount or time of the second reaction material functioning as an oxidant, the coverage characteristics or loading effect of the oxide film can be improved, and a decrease of throughput or an increase of COO can be previously prevented. Furthermore, since the second reaction material functioning as an oxidant is activated by irradiating ultraviolet light to the second reaction material, the second reaction material can be supplied to the substrate in a sufficiently activated state even at a temperature equal to or lower than 300° C.

(Supplementary Note 2)

In the method of Supplementary Note 1, it is preferable that the ultraviolet light be vacuum ultraviolet light.

(Supplementary Note 3)

In the method of Supplementary Note 1, it is preferable that the first reaction material be an organic compound.

(Supplementary Note 4)

In the method of Supplementary Note 1, it is preferable that the second reaction material be ozone.

(Supplementary Note 5)

In the method of Supplementary Note 1, it is preferable that the forming of the oxide film be performed by keeping the substrate at a constant temperature in a range from 20° C. to 600° C.

(Supplementary Note 6)

According to another preferred embodiment of the present invention, there is provided a substrate processing apparatus comprising:

a processing chamber in which a substrate is accommodated;

a heating unit configured to heat the substrate;

a first gas supply unit configured to supply a first reaction material to the processing chamber;

a second gas supply unit configured to supply a second reaction material containing oxygen atoms to the processing chamber;

an exhaust unit configured to exhaust an inside atmosphere of the processing chamber; and a control unit configured to control at least the heating unit, the first gas supply unit, and the second gas supply unit,

wherein the second gas supply unit comprises an ultraviolet generating mechanism configured to irradiate ultraviolet light to the second reaction material for activating the second reaction material, and

the control unit is configured to control the first gas supply unit, the second gas supply unit, the heating unit, the exhaust unit, and the ultraviolet generating mechanism, so as to form an oxide film on the substrate by alternately supplying the first reaction material and the second reaction material activated by the ultraviolet generating mechanism to the substrate while heating the substrate at a temperature lower than a self-decomposition temperature of the first reaction material.

According to the substrate processing apparatus of Supplementary Note 6, the ultraviolet generating mechanism is installed at the second gas supply unit, so that the second reaction material can be supplied to the substrate in a state where the second reaction material is activated. Owing to this, when the oxide film is formed, without having to increase the supply amount or time of the second reaction material functioning as an oxidant, the coverage characteristics or loading effect of the oxide film can be improved, and a decrease of throughput or an increase of COO can be previously prevented.

(Supplementary Note 7)

In the substrate processing apparatus of Supplementary Note 6, it is preferable that the ultraviolet generating mechanism be a vacuum ultraviolet lamp configured to emit vacuum ultraviolet light and comprising: a plasma excitation unit; an electrode connected to the plasma excitation unit for apply high-frequency power to the plasma excitation unit; and a discharge tube in which a discharge gas is filled, wherein the control unit be configured to control the second gas supply unit and the vacuum ultraviolet lamp and apply high-frequency power to the electrode for activating ozone.

(Supplementary Note 8)

In the substrate processing apparatus of Supplementary Note 6, it is preferable that the ultraviolet generating mechanism be a vacuum ultraviolet lamp configured to emit vacuum ultraviolet light and comprising: a dielectric tube made of a dielectric material and having a dual structure; a first electrode installed outside the dielectric tube; a second electrode installed inside the dielectric tube; and a high-frequency power source connected to the first electrode and the second electrode, wherein a discharge gas be filled in an hermetically sealed space of the dielectric tube, and the control unit be configured to activate the second reaction material by applying high-frequency power to the first and second electrodes from the high-frequency power source to excite the discharge gas and generate vacuum ultraviolet light.

Although a vertical batch type apparatus has been mainly explained, the present invention is not limited thereto. For example, the present invention can be applied to other apparatuses such as a single wafer type apparatus and a horizontal type apparatus.

What is claimed is:

1. A method of manufacturing a semiconductor device, comprising:
loading at least one substrate to a processing chamber;
forming an oxide film on the substrate by alternately supplying a first reaction material and a second reaction material containing oxygen atoms to the processing chamber while heating the substrate; and
unloading the substrate from the processing chamber,
wherein the forming of the oxide film is performed by keeping the substrate at a temperature lower than a self-decomposition temperature of the first reaction material and irradiating ultraviolet light to the second reaction material.

2. The method of claim 1, wherein the ultraviolet light is vacuum ultraviolet light.

3. The method of claim 1, wherein the first reaction material is an organic compound.

4. The method of claim 1, wherein the second reaction material is ozone.

5. The method of claim 1, wherein the forming of the oxide film is performed by keeping the substrate at a constant temperature in a range from 20° C. to 600° C.

6. A substrate processing apparatus comprising:
a processing chamber in which a substrate is accommodated;
a heating unit configured to heat the substrate;
a first gas supply unit configured to supply a first reaction material to the processing chamber;
a second gas supply unit configured to supply a second reaction material containing oxygen atoms to the processing chamber;
an exhaust unit configured to exhaust an inside atmosphere of the processing chamber; and
a control unit configured to control at least the heating unit, the first gas supply unit, and the second gas supply unit,
wherein the second gas supply unit comprises an ultraviolet generating mechanism configured to irradiate ultraviolet light to the second reaction material for activating the second reaction material, and
the control unit is configured to control the first gas supply unit, the second gas supply unit, the heating unit, the exhaust unit, and the ultraviolet generating mechanism, so as to form an oxide film on the substrate by alternately supplying the first reaction material and the second reaction material activated by the ultraviolet generating mechanism to the substrate while heating the substrate at a temperature lower than a self-decomposition temperature of the first reaction material.

7. The substrate processing apparatus of claim 6, wherein the ultraviolet generating mechanism is a vacuum ultraviolet lamp which is configured to emit vacuum ultraviolet light and comprises:
a plasma excitation unit;
an electrode connected to the plasma excitation unit for apply high-frequency power to the plasma excitation unit; and
a discharge tube in which a discharge gas is filled,
wherein the control unit is configured to control the second gas supply unit and the vacuum ultraviolet lamp and apply high-frequency power to the electrode for activating ozone.

8. The substrate processing apparatus of claim 6, wherein the ultraviolet generating mechanism is a vacuum ultraviolet lamp which is configured to emit vacuum ultraviolet light and comprises:
a dielectric tube made of a dielectric material and having a dual structure;
a first electrode installed outside the dielectric tube;
a second electrode installed inside the dielectric tube; and
a high-frequency power source connected to the first electrode and the second electrode,
wherein a discharge gas is filled in an hermetically sealed space of the dielectric tube, and
the control unit is configured to activate the second reaction material by applying high-frequency power to the first and second electrodes from the high-frequency power source to excite the discharge gas and generate vacuum ultraviolet light.
